(19) United States
(12) Patent Application Publication
(10) Pub. No.: US 2014/0126273 A1
(43) Pub. Date: May 8, 2014

(54) POWER MANAGEMENT SRAM GLOBAL BIT LINE PRECHARGE CIRCUIT

(71) Applicant: INTERNATIONAL BUSINESS MACHINES CORPORATION, Armonk, NY (US)

(72) Inventors: Derick G. Behrends, Rochester, MN (US); Todd A. Christensen, Rochester, MN (US); Travis R. Hebig, Rochester, MN (US); Michael Launsbach, Rochester, MN (US)

(73) Assignee: International Business Machines Corporation, Armonk, NY (US)

(21) Appl. No.: 13/667,603

(22) Filed: Nov. 2, 2012

(51) Int. Cl. G11C 11/00; G06F 17/50

(52) U.S. Cl. 365/154; 716/102

(57) ABSTRACT

A domino static random access memory (SRAM) having one or more SRAM memory cells connected with a local bit line is disclosed. The SRAM may include a precharge device connected between a voltage supply and the local bit line, and global bit line (GBL) discharge logic connected between a local bit line and a GBL. The GBL discharge logic transfers a logic value of the local bit line to the GBL during a read operation. GBL precharge logic connects the GBL to a global precharge input. The GBL precharge logic is adapted to draw the GBL to a precharge voltage above a discharge voltage and below a supply voltage during a precharge operation.

### TECHNICAL FIELD

The present disclosure relates to a static random-access memory (SRAM). In particular, this disclosure relates to global bit line precharge for an SRAM.

### BACKGROUND

SRAMs may be arranged in a domino-logic structure in which two or more SRAM cells are connected in parallel to two local bit lines. One of the two local bit lines is coupled to a global bit line (GBL) through a GBL discharge logic. Both the local and global bit lines in a domino SRAM are precharged high before a read operation, and may be discharged, or “pulled down” to ground during a read operation. A particular cell is selected for reading by activating the cell's word line. One of the two precharged local bit lines coupled to the selected cell may be discharged during a read operation. If the discharged local bit line is the one that is coupled to the GBL, the discharge of the local bit line activates logic that discharges the GBL.

One of ordinary skill in the art will recognize that “0” and “1” refer to logical “zero” and “one” values, respectively.

FIG. 1 is a schematic representation of a portion of a prior art SRAM circuit 100 having a column of SRAM cells 110, a GBL 106, a local eval logic 122, and a GBL discharge logic 120, and a GBL precharge logic 111. Each SRAM cell 110 includes a pair of cross-coupled inverters, 130, 132. SRAM cells are connected to the local eval logic 122 through a local bit line true (LBLT) 102 and a local bit line complement (LBLC) 104. The LBLT and the LBLC are precharged by a local bit line precharge line (LBL_PCH) 114 and transistors 1P1 and 1P2. A write true line (WT) 126 and its associated transistors 1N3 and 1N6, a write complement line (WC) 124 and its associated transistors 1N4 and 1N5, and a write enable line (WE) 118 and its associated transistor 1N7 control the write operations of the cell 110. The GBL 106 is precharged to Vdd by a GBL precharge line (GBL_PCH) 112 and the GBL precharge logic 111. An inverter 105 drives an output 107 with the complement of the GBL.

A read operation employs the GBL discharge logic 120. As an illustration, to read a 1 from the cell 110 in the SRAM column, a word line (WL) 108 turns on pass transistors 1N1 and 1N2. When the 1 is read, the LBLT 102 remains high while the LBLC 104 is pulled down. The value on the LBLC 104 is inverted to a 1 by an inverter 116, which turns on an N-channel field-effect (NFET) transistor 1N8. The transistor 1N8 pulls down the precharged GBL 106 to ground (GND) 710 (In FIG. 7), effectively placing the complement of the 1 on the GBL 106.

The read operation is immediately followed by a GBL precharge operation. The GBL precharge operation is initiated by the transition of the GBL_PCH signal 112 to 0, which turns on a PFET transistor 1P3. When on, 1P3 provides a precharge path between Vdd and the GBL, subsequently precharging the GBL to a high voltage level. The GBL_PCH signal 112 signal level then returns to a 1 (inactive) value before the next read operation. The inverter 105 drives the output 107 with the complement value of the GBL 106.

### SUMMARY

One embodiment is directed to a domino static random access memory (SRAM). The SRAM may include two or more SRAM memory cells connected with a local bit line. In addition, the SRAM may also include a precharge device connected between a voltage supply and the local bit line, and global bit line (GBL) discharge logic connected between the local bit line and a GBL. The GBL discharge logic may transfer a logic value of the local bit line to the GBL during a read operation. The SRAM may also include a GBL precharge logic connected between the GBL and the global precharge input. The GBL precharge logic is adapted to draw the GBL to a precharge voltage above a discharge voltage and below a supply voltage during a precharge operation.

Another embodiment is directed to a method for operating a domino static random access memory (SRAM). The method may include precharging a local bit line, the local bit line being connected to two or more SRAM cells. In addition, the method may include precharging a global bit line (GBL) to a precharge voltage between the discharge voltage level and a supply voltage. Data may be read from the SRAM, and a 0 data value stored in one of the SRAM cells may drive the local bit line to a discharge voltage. The local bit line discharge voltage then enables a GBL discharge logic to discharge the GBL to a GBL discharge voltage. The method may also include discharging the GBL to a GBL discharge voltage one PFET threshold (Vt) above GND. The method may also include turning on a PFET to charge the GBL during a precharge operation, and using a precharge feedback path to turn off the PFET when the GBL reaches the GBL precharge voltage. In addition, an NFET may be turned on to charge the GBL during a precharge operation.

A further embodiment is directed to a design structure for producing an SRAM. Aspects of the various embodiments may allow power consumption in an SRAM to be reduced.

### BRIEF DESCRIPTION OF THE DRAWINGS

The drawings included in the present application are incorporated into, and form part of, the specification. They illustrate embodiments of the present invention and, along with the description, serve to explain the principles of the invention. The drawings are only illustrative of embodiments of the invention and do not limit the invention.

FIG. 1 is a schematic representation of a portion of a prior art SRAM circuit having global bit line (GBL) precharge logic.

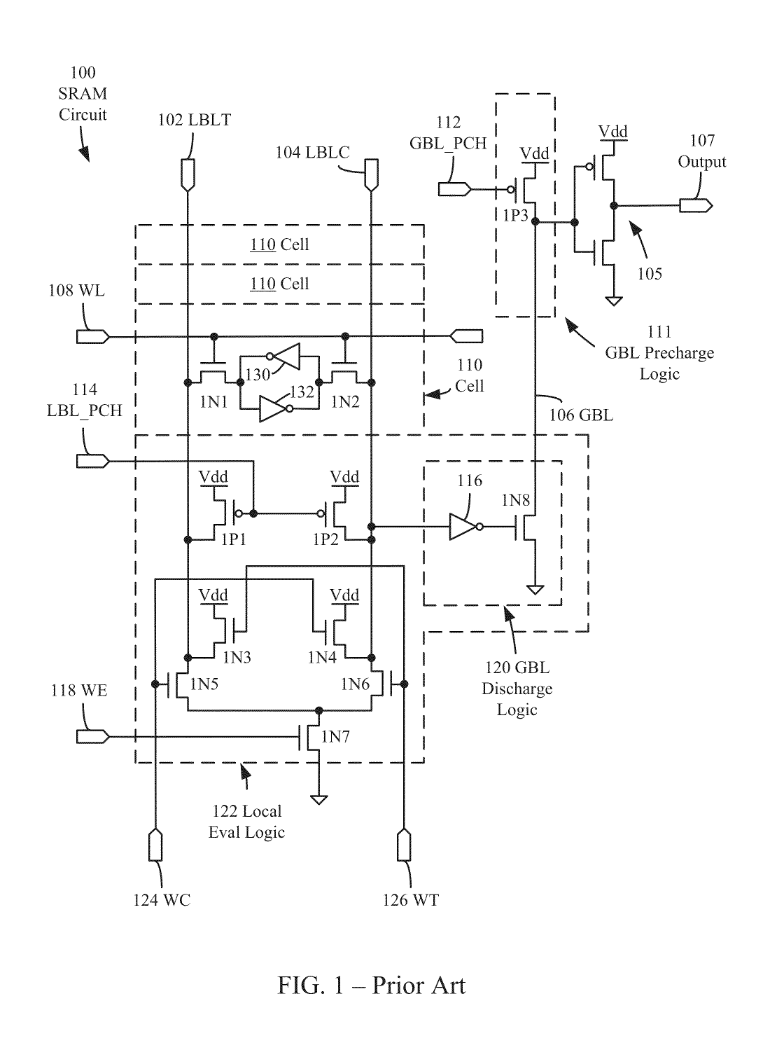

FIG. 2 is a diagrammatic representation of a portion of an SRAM including a column of SRAM cells, and GBL precharge logic and a GBL according to embodiments of the invention.

FIG. 3 is a schematic representation of the GBL precharge circuit of FIG. 2, according to one embodiment of the invention.

FIG. 4 is a schematic representation of the GBL precharge circuit of FIG. 2, according to an alternate embodiment of the invention.

FIG. 5 is a schematic representation of the GBL precharge circuit of FIG. 2, according to yet another embodiment of the invention.

FIG. 6 is a schematic representation of the GBL precharge circuit of FIG. 2, according to yet another embodiment of the invention.

FIG. 7 is a waveform diagram of a precharge operation of an SRAM GBL, according to embodiments of the invention.

FIG. 8 is a waveform diagram of a precharge operation of an SRAM GBL, according to alternate embodiments of the invention.

FIG. 9 is a flow diagram of a design process used in semiconductor design, manufacture, and/or test of the inventive SRAM depicted in FIGS. 2, 3, 4, 5, 6, 7 and 8, according to embodiments of the invention.

In the drawings and the Detailed Description, like numbers generally refer to like components, parts, steps, and processes.

### DETAILED DESCRIPTION

According to embodiments of the invention, an SRAM global bit line (GBL) may be precharged through a GBL precharge logic to a voltage level above a discharge voltage, but below a supply voltage. An SRAM column may contain a local evaluation logic and one or more SRAM cells, each cell storing a 1 or a 0. The SRAM column may be coupled to the GBL through a global discharge logic. During an SRAM read operation, a local bit line true (LBLT) or a local bit line complement (LBLC) may receive a 0 from an SRAM cell. The LBLT or LBLC may be connected to the input of the global discharge logic. The 0 on the input to the global discharge logic may cause the GBL to be discharged, thus transferring the 0 to the GBL. The GBL may be subsequently precharged to Vdd for a next read operation.

Power reduction and management are becoming increasingly important as circuit technology advances. Fully precharging GBLs to Vdd in SRAM circuits requires energy and resources. Decreasing SRAM circuit power consumption may enable chips with lower overall power consumption. An NFET may be used in the precharge and keeper paths between the supply voltage Vdd and the GBL. The NFET device electrical characteristics only allow the GBL to be precharged to a voltage level of one NFET threshold voltage (Vt) below Vdd, according to embodiments of the invention. A reduction in GBL voltage swing may result, causing a reduction of required read operation power. Reduction of read operation power may provide opportunities for SRAM and overall chip power management.

As may be seen from the following equation, the reduction of overall GBL voltage swing may reduce the energy consumed to charge and discharge the GBL:

P=A×C×V²×F

### Where:

P=chip dynamic power consumption (W)
A=activity factor (coefficient with values between 0 and 1 indicating signal activity level)
C=capacitance of nodes being charged and discharged (F)
V=signal voltage swing (V)
F=switching frequency (Hz)

Reducing the difference in voltage between the precharge voltage and the discharge voltage reduces V in the equation, which may in turn exponentially reduce power used in a read operation.

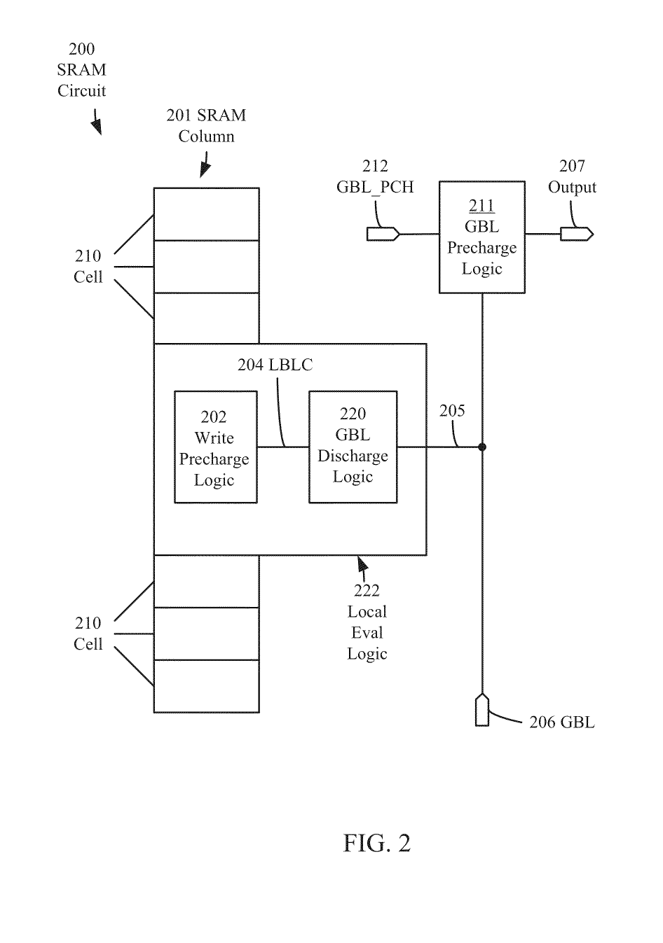

FIG. 2 is a diagrammatic representation of a portion of an SRAM circuit having a GBL discharge logic 220 and a GBL precharge logic 211 coupled to a GBL 206, according to embodiments of the invention. The terms “true” and “complement” are used only to distinguish two similar but inversely operable lines.

An SRAM circuit 200 may contain a column 201 coupled to the GBL 206. The column may have a plurality of groups of SRAM cells 210 and a local evaluation logic 222 for each group. A GBL discharge line 205 may couple the local evaluation logic 222 to the GBL 206. If a 1 is read from a cell, a LBLC 204 communicates with the GBL discharge logic 220 to discharge the GBL 206.

In embodiments of the invention, partial GBL precharge may be carried out through the GBL precharge logic 211 which may use a switch, such as an N-channel field effect transistor (NFET) or a P-channel field effect transistor (PFET) operated by a GBL_PCH 212 signal. Embodiments of the invention may also hold or “keep” the GBL voltage level once it has been precharged. Holding the GBL voltage level may be accomplished through the use of a keeper circuit which is activated through feedback circuitry. So long as there is no precharge path for the GBL 206, the GBL 206 may not be pulled up. Once a signal on the GBL_PCH input 212 enables a precharge path for the GBL 206, the GBL 206 may be partially precharged by the GBL precharge logic 211. The GBL precharge logic may have a gate operated by a global precharge signal.

In embodiments of the invention the GBL 206 may be discharged from a previous read operation. During a read operation, local evaluation logic, such as 222, reads a data value from an SRAM cell 210, and transfers either the true or complement of that value to the GBL 206 through the GBL discharge logic 220. To place a 0 value on the GBL 206, the GBL discharge logic 220 is enabled and the GBL 206 is subsequently discharged or “pulled down.” The GBL 206 must be precharged to a voltage corresponding to a high or 1 value before the start of the next read operation.

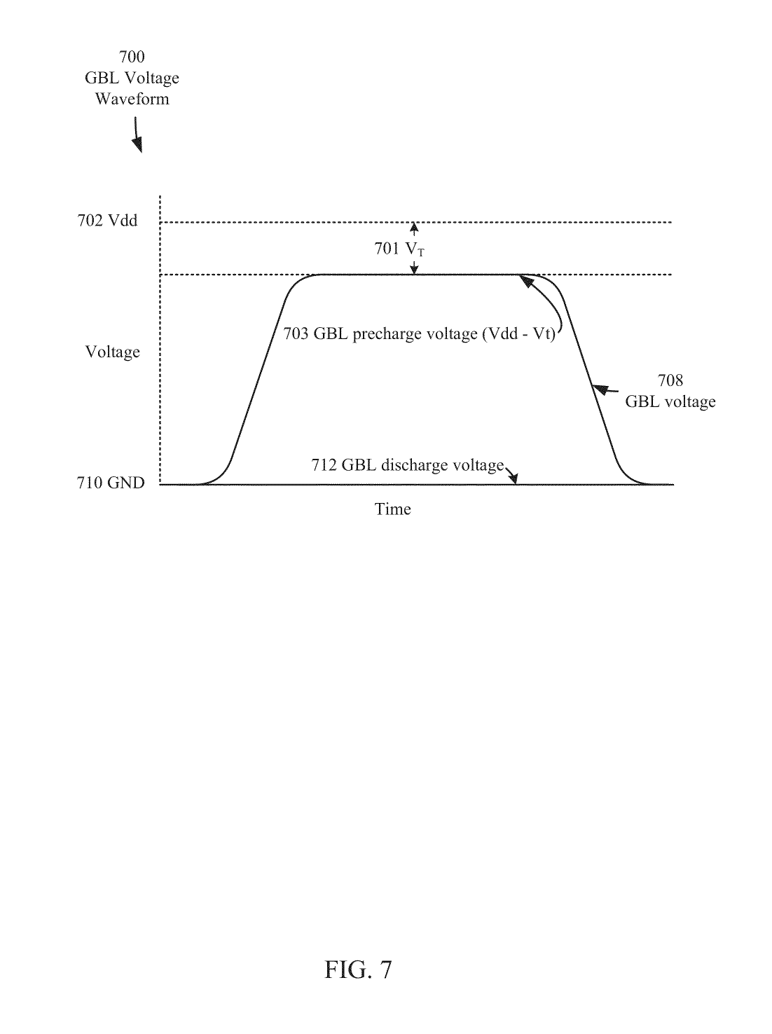

Various embodiments may contain a section of circuitry within the GBL precharge logic 211 that precharges the GBL 206, and another keeper circuit that holds the GBL 206 at a GBL precharge voltage 703 (in FIG. 7). Both precharge and keeper circuits provide a connection between Vdd and GBL 206. The purpose of the precharge circuit is to rapidly pull up the GBL 206 to a 1 state, to prepare it for the next read operation, during which it may be discharged. The precharge circuit connects GBL 206 to Vdd in response to a 0 level on the GBL_PCH 212 input. After the GBL 206 has been pulled to a 1, the GBL precharge logic 220 is disabled, eliminating the precharge connection between Vdd and GBL 206.

The purpose of the keeper circuit, such as 322, is to counteract any charge leakage that would cause the GBL voltage to decrease from its precharged level over time. If the voltage of the GBL 206 is allowed to decrease due to leakage, it may incorrectly represent a 0 value, causing a data read error in the SRAM. The keeper circuit connects the GBL 206 to Vdd when the GBL voltage is sensed at a 1 voltage level. The keeper circuit maintains a relatively weak connection between the GBL 206 and Vdd, which may generally be overcome without difficulty by the GBL discharge logic 220. When the GBL 206 is discharged or pulled to a 0 level, the keeper circuit disables its connection between Vdd and GBL 206.

The NFET transistors used in the precharge and keeper circuit paths provide a voltage drop between Vdd and the GBL 206. The connection scheme and electrical properties of the NFET transistors ensure a voltage drop between NFET source and drain terminals, causing the GBL precharge voltage 703 (in FIG. 7) to be one NFET threshold voltage (Vt) 701 (in FIG. 7) below Vdd 702 (in FIG. 7).

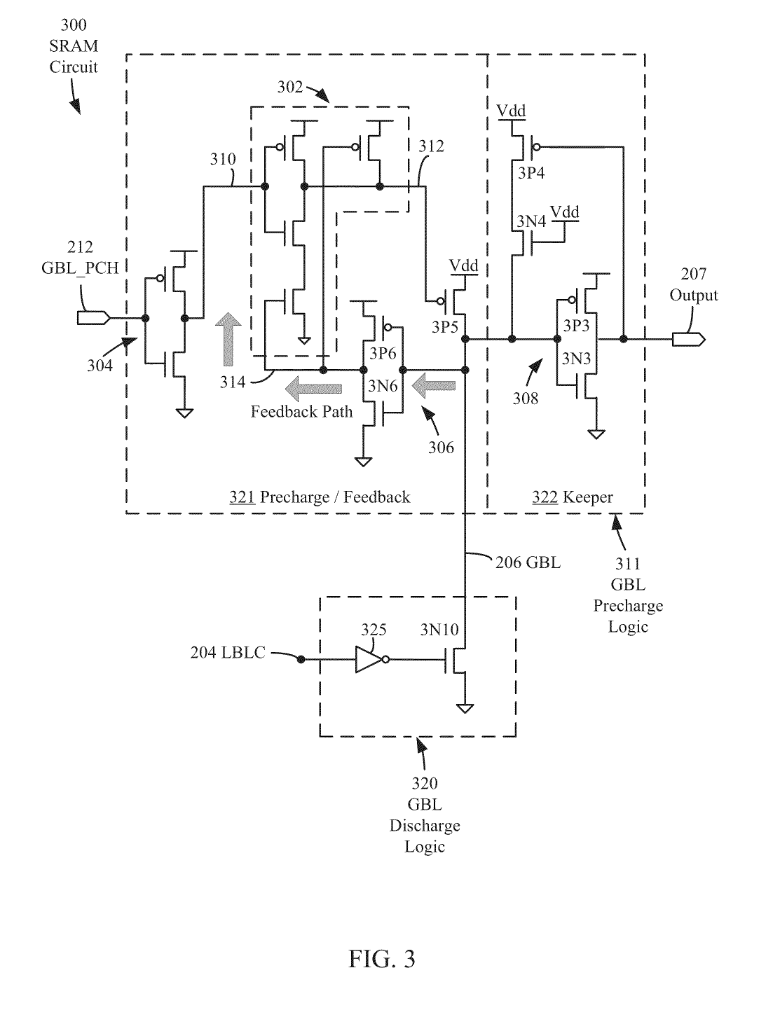

The transistors depicted in FIGS. 3, 4, 5, and 6 will be recognized by one with ordinary skill in the art to be arranged to form logic functions including inverters, NAND gates, pull-up and pull-down devices.

FIG. 3 is a schematic representation of a portion of an SRAM circuit 300 having a GBL precharge logic 311 that may precharge the GBL 206, according to an embodiment of the invention. The GBL precharge logic includes a precharge/feedback circuit 321 and a keeper circuit 322.

The purpose of the precharge/feedback circuit 321 is to precharge the GBL 206 to a logic 1 value, corresponding to a voltage above a discharge voltage, but below a supply voltage Vdd (702) (in FIG. 7). The purpose of the keeper circuit 322 is to keep the GBL 206 at a logic 1 value, once the precharge/feedback circuit 321 has precharged the GBL 206. The keeper circuit counteracts any charge leakage from the GBL 206 that may decrease the GBL voltage 708 (in FIG. 7) over time, and change its logic state from a 1 to a 0.

The precharge/feedback circuit 321 includes a GBL precharge PFET 3P5, with a source connected to Vdd, and a drain connected to the GBL 206. 3P5 is used to connect the GBL 206 to Vdd during the precharge operation. The gate of 3P5 is connected to a precharge feedback path that controls its operation. The precharge feedback path is formed by an inverter 306 and a NAND gate 302. The input of inverter 306 is connected to the GBL 206, and its output is connected to a first input of the NAND gate 302. The input of an inverter 304 is connected to the GBL_PCH 212 signal, and its output is connected to a second input of NAND gate 302. The output of NAND gate 302 is connected to the gate of PFET 3P5.

The keeper circuit 322 includes a GBL keeper PFET 3P4, with a source connected to Vdd, and a drain connected to the drain of NFET 3N4. NFET 3N4 has a source connected to the GBL 206, and a gate connected to Vdd. The series connected transistor pair 3P4 and 3N4 is used to provide a connection between Vdd and the GBL 206 to maintain the GBL voltage 708 (in FIG. 7) at the GBL precharge voltage 703 (in FIG. 7) following the precharge operation. The gate of 3P4 is connected to the inverter 308 that controls its operation. The inverter 308 drives the gate of 3P4 with the complement of the GBL 206 logical state.

As an illustration of a precharge operation, it is assumed that the global precharge signal on input GBL_PCH 212 is initially a 1 (inactive), and that the GBL 206 is a 0, or discharged state, ready to be precharged. The initial states of GBL_PCH 212 and GBL 206 cause nodes 312 and 314 to be a 1, and node 310 to be a 0.

The precharge operation begins with the global precharge signal changing from a 1 to a 0. When both the global precharge signal and the GBL 206 are 0, the inverters 304 and 306 drive is on nodes 310 and 314 respectively. The NAND gate 302 responds to the 1 inputs on nodes 310 and 314, and drives a 0 on node 312. The 0 on node 312 turns on 3P5, connecting the GBL 206 to Vdd, rapidly increasing the GBL voltage 708 (in FIG. 7) from the GBL discharge voltage 712 (in FIG. 7).

As the voltage level of the GBL 206 rises from the GBL discharge voltage 712 (in FIG. 7), and crosses the switching threshold of inverter 306, inverter 306 drives a 0 on node 314. The 0 on node 314 causes the NAND gate 302 to drive a 1 on node 312. The 1 on node 312 shuts off PFET 3P5, causing the precharging of the GBL 206 to cease. The described precharge feedback path creates a self-timed circuit that only enables the GBL 206 precharge as long as is necessary to raise the GBL voltage 708 (in FIG. 7) to a GBL precharge voltage 703 (in FIG. 7). A designer may specify the width/length ratios of transistors 3P6 and 3N6 to create an inverter 306 switching threshold that is slightly less than the GBL precharge voltage 703 (in FIG. 7).

Once the GBL 206 voltage exceeds the switching threshold of an inverter 308, the inverter 308 drives a 0 on a node 207. A 0 on the node 207 turns on transistor 3P4, creating a keeper path between Vdd and GBL 206, through transistors 3P4 and 3N4. NFET transistor 3N4 has its gate connected to Vdd, its drain connected to the drain of 3P4, and its source connected to the GBL 206. Once the keeper path has been enabled, the GBL_PCH signal may be released by returning to a 1, and the GBL 206 may be maintained at a 1 by the keeper circuit 322. A designer may specify the width/length ratios of transistors 3P3 and 3N3 to create an inverter 308 switching threshold that is less than the inverter 306 switching threshold, approximating one half of Vdd. Providing the inverter 308 with a lower switching threshold than the inverter 306 ensures that the keeper circuit may become and stay activated despite minor variations in the GBL precharge voltage 703 (in FIG. 7). The switching threshold of inverter 308 may also be tuned to provide suitable noise margins between the GBL precharge voltage and GBL discharge voltage 712 (in FIG. 7).

In a subsequent read operation, the LBLC line 204 may be driven to 0, causing inverter 325 to drive the gate of NFET 3N10 to a 1. NFET 3N10 may turn on, creating a discharge path between the GBL 206 and ground. A designer may specify the width of NFET 3N10 to be much greater than the width of NFET 3N4, thereby enabling the keeper voltage level of NFET 3N4 to be generally overcome without difficulty by the NFET 3N10 when it turns on.

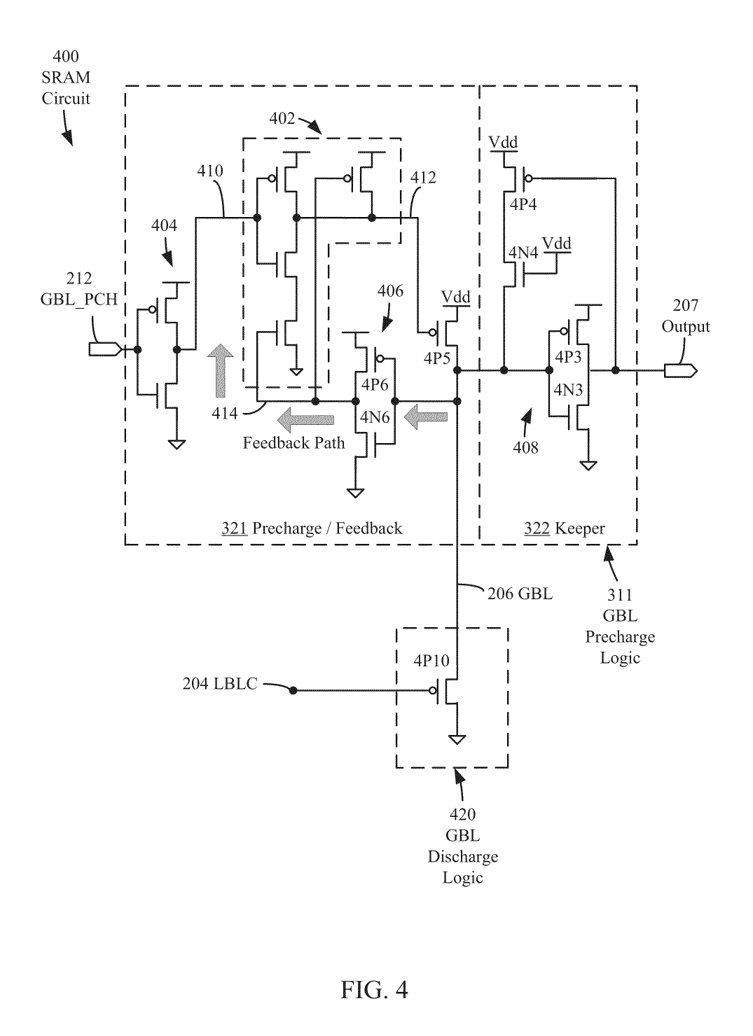

FIG. 4 is a schematic representation of a portion of an SRAM circuit 400 having GBL discharge logic 420, and GBL precharge logic 311 that may precharge the GBL 206, according to an alternate embodiment of the invention. Referring to FIG. 4, the GBL precharge logic 311 is identical to the GBL precharge logic 311 previously described. Following the previously described precharge operation, in a subsequent read operation, the LBLC line 204 and the gate of a PFET 4P10 of GBL discharge logic 420 may be driven to 0, turning on PFET 4P10 and creating a discharge path between the GBL 206 and ground.

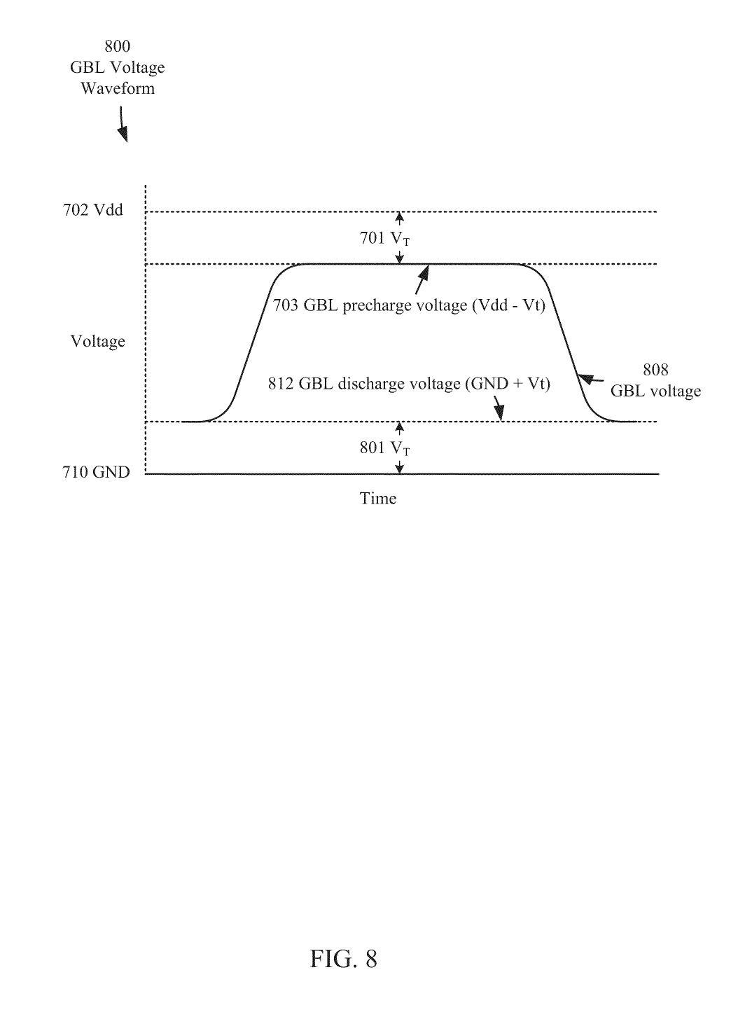

The use of PFET 4P10 as a discharge device ensures that the GBL discharge voltage 812 (in FIG. 8) may be one PFET voltage threshold (Vt) 801 (in FIG. 8) above ground 710 (in FIG. 8). A designer may specify the width of PFET 4P10 to be much greater than the width of NFET 4N4, thereby enabling the keeper voltage level of NFET 4N4 to be generally overcome without difficulty by the PFET 4P10 when it turns on.

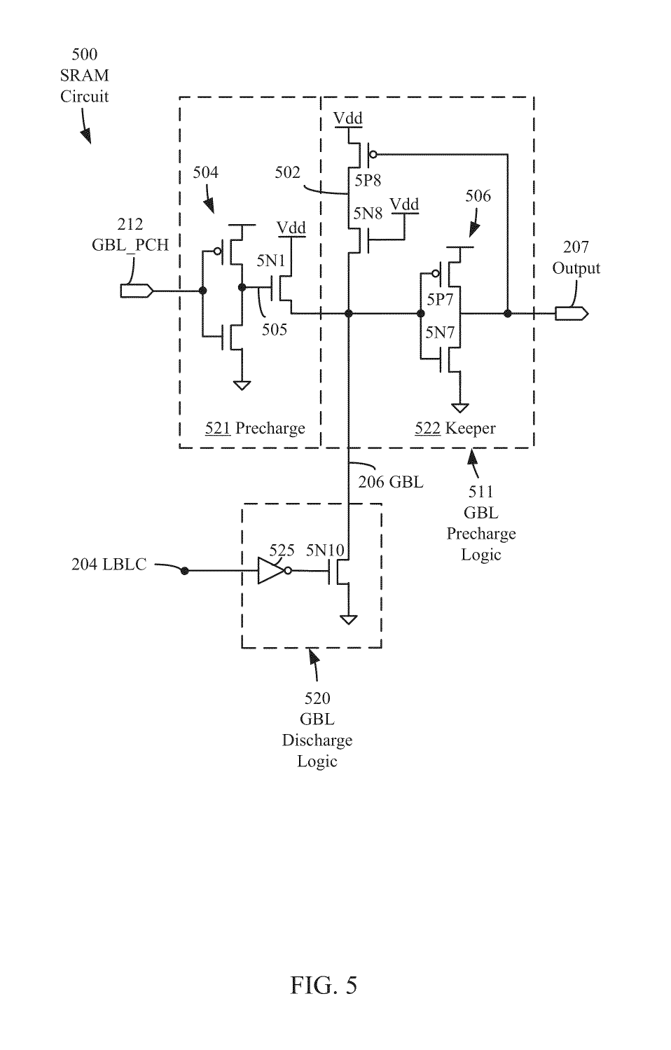

FIG. 5 is a schematic representation of a portion of an SRAM circuit 500 having a GBL precharge logic 511 that may precharge the GBL 206, according to an embodiment of the invention. The GBL precharge logic includes a precharge circuit 521 and a keeper circuit 522.

The purpose of the precharge circuit 521 is to precharge the GBL 206 to a logic 1 value, corresponding to a voltage above a discharge voltage, but below a supply voltage (Vdd). The purpose of the keeper circuit 522 is to keep the GBL 206 at a logic 1 value, once the precharge circuit 521 has precharged the GBL 206.

The precharge circuit 521 includes a GBL precharge NFET 5N1, with a source connected to the GBL 206, and a drain connected to Vdd. NFET 5N1 is used to connect the GBL 206 to Vdd during the precharge operation. The gate of 5N1 is coupled to the GBL_PCH 212 input that controls its operation. Inverter 504 drives the gate of 5N1 with the complement of the global precharge signal from input GBL_PCH 212.

The keeper circuit 522 includes a GBL keeper PFET 5P8, with a source connected to Vdd, and a drain connected to the drain of NFET 5N8. NFET 5N8 has a source connected to the GBL 206, and a gate connected to Vdd. The series connected transistor pair 5P8 and 5N8 is used to provide a connection between Vdd and the GBL 206 to maintain the GBL voltage at the GBL precharge voltage 703 (in FIG. 7) following the precharge operation. The gate of 5P8 is connected to the output of the inverter 506 that controls its operation. The inverter 506 drives the gate of 5P8 with the complement of the GBL 206.

As an illustration of a precharge operation, it is assumed that the global precharge signal on input GBL_PCH 212 is initially a 1 (inactive), and that the GBL 206 is a 0, or discharged state, ready to be precharged. The initial states of GBL_PCH 212 and GBL 206 cause node 207 to be a 1, and node 505 to be a 0.

The precharge operation begins with the global precharge signal changing from a 1 to a 0. Inverter 504 then drives a 1 on the gate of NFET 5N1. The NFET 5N1 turns on, connecting the GBL 206 to Vdd, rapidly increasing the GBL voltage 708 (in FIG. 7) from the GBL discharge voltage 712 (in FIG. 7).

As the voltage level of the GBL 206 rises from the GBL discharge voltage 712 (in FIG. 7), and crosses the switching threshold of inverter 506, inverter 506 drives a 0 on node 207. The 0 on node 207 turns on PFET 5P8, connecting the GBL 206 to Vdd through the keeper path of 5P8 and 5N8. Once the keeper path has been enabled, the GBL_PCH 212 signal may be released (return to a 1 value) and the GBL 206 may be maintained at a 1 (high) level.

A designer may specify the width/length ratios of transistors 5P7 and 5N7 to create an inverter 506 switching threshold that provides suitable noise margins between the GBL precharge voltage 703 (in FIG. 7) and GBL discharge voltage 712 (in FIG. 7).

In a subsequent read operation, the LBLC line 204 may be driven to 0, causing inverter 525 to drive the gate of NFET 5N10 to a 1. NFET 5N10 may turn on, creating a discharge path between the GBL 206 and ground. A designer may specify the width of NFET 5N10 to be much greater than the width of PFET 5P8, making PFET 5P8 generally overcome without difficulty by the NFET 5N10.

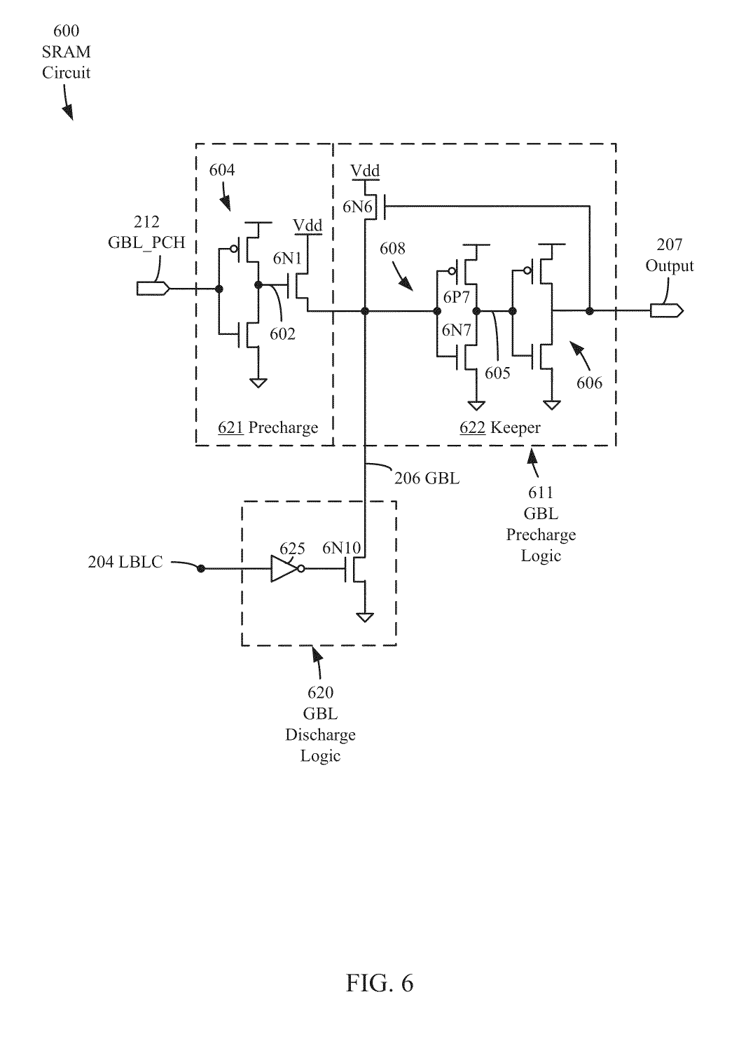

FIG. 6 is a schematic representation of a portion of an SRAM circuit 600 having the GBL precharge logic 611 that may precharge the GBL 206, according to an embodiment of the invention. The GBL precharge logic 611 includes a precharge circuit 621 and a keeper circuit 622.

The purpose of the precharge circuit 621 is to precharge the GBL 206 to a logic 1 value, corresponding to a voltage above a discharge voltage, but below a supply voltage (Vdd). The purpose of the keeper circuit 622 is to keep the GBL 206 at a logic 1 value, once the precharge circuit has precharged the GBL 206.

The precharge circuit 621 includes a GBL precharge NFET 6N1, with a source connected to the GBL 206, and a drain connected to Vdd. 6N1 is used to connect the GBL 206 to Vdd during the precharge operation. The gate of 6N1 is coupled to the GBL_PCH 212 input that controls its operation. Inverter 604 drives the gate of 6N1 with the complement of the global precharge signal from input GBL_PCH 212.

The keeper circuit 622 includes a GBL keeper NFET 6N6, with a source connected to the GBL 206, and a drain connected to Vdd. NFET 6N6 is used to provide a connection between Vdd and the GBL 206 to maintain the GBL voltage 708 (in FIG. 7) at the GBL precharge voltage 703 (in FIG. 7) following the precharge operation. The gate of 6N6 is connected to the output of the inverter 606 that controls its operation. The series connected pair of inverters 608 and 606 drive the gate of 6N6 with a copy of the signal on the GBL 206.

As an illustration of a precharge operation, it is assumed that the global precharge signal on input GBL_PCH 212 is initially a 1 (inactive), and that the GBL 206 is a 0, or discharged state, ready to be precharged. The initial states of GBL_PCH 212 and GBL 206 cause node 605 to be a 1, and nodes 602 and 207 to be a 0.

The precharge operation begins with the global precharge signal on GBL_PCH 212 changing from a 1 to a 0. Inverter 604 then drives a 1 on the gate of NFET 6N1. The NFET 6N1 turns on, connecting the GBL 206 to Vdd, rapidly increasing the GBL voltage 708 (in FIG. 7) from the GBL discharge voltage 712 (in FIG. 7).

As the voltage of the GBL 206 rises from the GBL discharge voltage 712 (in FIG. 7), and crosses the switching threshold of inverter 608, inverter 608 drives a 0 on node 605. Inverter 606 then drives a 1 on node 207. The 1 on node 207 turns on NFET 6N6, connecting the GBL 206 to Vdd through the keeper path of NFET 6N6. Once the keeper path has been enabled, the GBL_PCH 212 signal may be released (return to a 1 value) and the GBL 206 may be maintained at a 1 (high) level.

A designer may specify the width/length ratios of transistors 6P7 and 6N7 to create an inverter 608 switching threshold that provides suitable noise margins between the GBL precharge voltage 703 (in FIG. 7) and GBL discharge voltage 712 (in FIG. 7).

In a subsequent read operation, the LBLC line 204 may be driven to 0, causing inverter 625 to drive the gate of NFET 6N10 to a 1. NFET 6N10 may turn on, creating a discharge path between the GBL 206 and ground. A designer may specify the width of NFET 6N10 to be much greater than the width of NFET 6N6, thereby enabling the keeper voltage level of NFET 6N6 to be generally overcome without difficulty by the NFET 6N10 when it turns on.

One of ordinary skill in the art will appreciate that the embodiments depicted in FIGS. 3 and 4 may produce shorter GBL rise times, and less roll off than the embodiments depicted in FIGS. 5 and 6, which may be desirable. The performance difference may arise from an NFET in the GBL precharge path having a gate to source voltage less than the NFET threshold voltage during the latter part of the GBL precharge operation, limiting the current the NFET may source to the GBL to precharge it.

FIG. 7 is a waveform diagram of the GBL 206 (in FIG. 2) voltage level during a precharge operation of an SRAM cell according to embodiments of the invention. FIG. 7 is an exemplary depiction that illustrates a typical GBL voltage 708 swing between the GBL discharge voltage 712 and the GBL precharge voltage 703. In this example, GBL discharge voltage 712 may be identical to the ground (GND) 710. Other embodiments may employ GBL discharge voltages that differ from ground (GND).

Prior to a read operation, the GBL 206 (in FIG. 2) may be precharged to the GBL precharge voltage 703. The GBL precharge voltage 703 may be one NFET threshold voltage (Vt) 701 below Vdd 702. When a 1 is read from a cell 210 (in FIG. 2), the GBL discharge logic 220 (in FIG. 2) discharges the GBL 206 (in FIG. 2) to a GBL discharge voltage 712.

In an exemplary embodiment of the invention, the NFET threshold (Vt) 701 may be approximately ten percent of the supply voltage Vdd 702. In another exemplary embodiment of the invention, the NFET threshold (Vt) 701 may be approximately twenty percent of the supply voltage Vdd. A generally accepted range of (Vt) 701 values lies between approximately ten and thirty percent of supply voltage Vdd, but this range does not limit possible (Vt) 701 values in any way. NFET threshold voltages may vary according to several factors, including but not limited to various design parameters and semiconductor process variations. One skilled in the art of SRAM design may understand how various design parameters may be determined to effect a change in NFET threshold voltages (Vt) 701.

FIG. 8 is a waveform diagram of the GBL 206 (in FIG. 2) voltage level during a precharge operation of an SRAM cell according to alternate embodiments of the invention. FIG. 8 is an exemplary depiction that illustrates a typical GBL voltage 808 swing between the GBL discharge voltage 812 and the GBL precharge voltage 703. In this example, GBL discharge voltage is one PFET voltage threshold (Vt) 801 above ground (GND).

Prior to a read operation, the GBL 206 (in FIG. 2) may be precharged to the GBL precharge voltage 703. The GBL precharge voltage 703 may be one NFET threshold voltage (Vt) 701 below Vdd 702. When a 1 is read from a cell, the GBL discharge logic 220 (in FIG. 2) discharges the GBL 206 (in FIG. 2) to a GBL discharge voltage 812. The GBL discharge voltage may be one PFET threshold voltage (Vt) 801 above GND 710.

In an exemplary embodiment of the invention, the PFET threshold (Vt) 801 may be approximately ten percent of the supply voltage Vdd 702. In another exemplary embodiment of the invention, the PFET threshold (Vt) 801 may be approximately twenty percent of the supply voltage Vdd 702. A generally accepted range of Vt 801 values lies between approximately ten and thirty percent of supply voltage Vdd 702, but this range does not limit possible Vt 701 values in any way. PFET threshold voltages may vary according to several factors, including but not limited to various design parameters and semiconductor process variations. One skilled in the art of SRAM design may understand how various design parameters may be determined to effect a change in NFET and PFET threshold voltages (Vt).

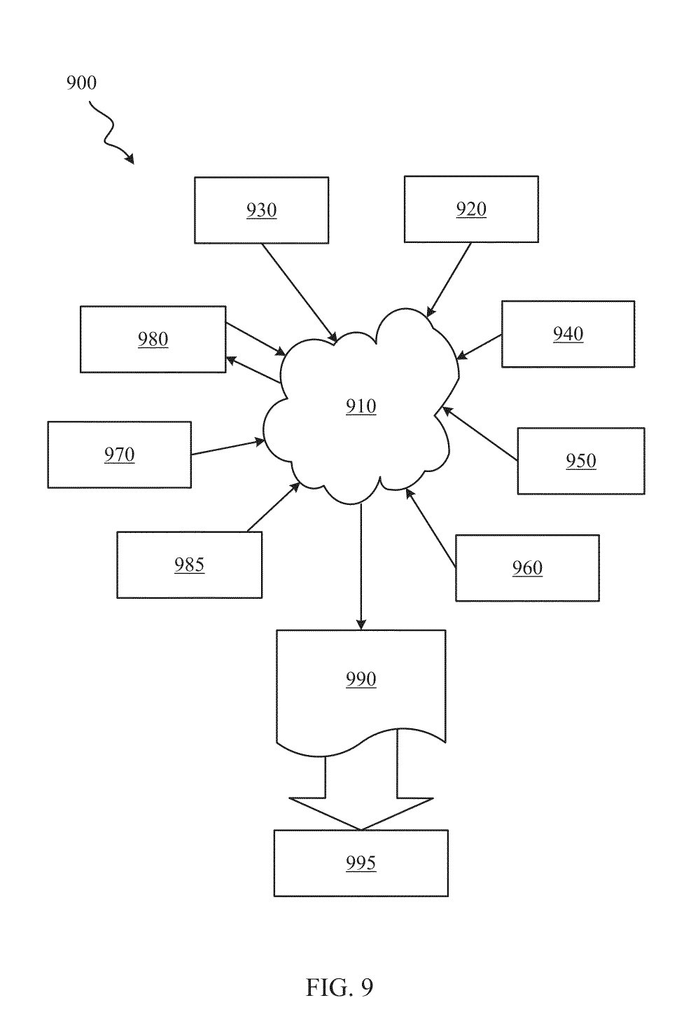

FIG. 9 illustrates multiple design structures 900 including an input design structure 920 that is preferably processed by a design process. Design structure 920 may be a logical simulation design structure generated and processed by design process 910 to produce a logically equivalent functional representation of a hardware device. Design structure 920 may alternatively include data or program instructions that, when processed by design process 910, generate a functional representation of the physical structure of a hardware device. Whether representing functional or structural design features, design structure 920 may be generated using electronic computer-aided design, such as that implemented by a core developer/designer. When encoded on a machine-readable data transmission, gate array, or storage medium, design structure 920 may be accessed and processed by one or more hardware or software modules within design process 910 to simulate or otherwise functionally represent an electronic component, circuit, electronic or logic module, apparatus, device, or system such as those shown in FIGS. 3, 4, 5, and 6. As such, design structure 920 may include files or other data structures including human or machine-readable source code, complied structures, and computer-executable code structures that, when processed by a design or simulation data processing system, functionally simulate or otherwise represent circuits or other levels of hardware logic design. Such data structures may include hardware-description language design entities or other data structures conforming to or compatible with lower-level HDL design languages such as Verilog and VHDL, or higher level design languages such as C or C++.

Design process 910 preferably employs and incorporates hardware or software modules for synthesizing, translating, or otherwise processing a design/simulation functional equivalent of the components, circuits, devices, or logic structures shown in FIGS. 3, 4, 5, and 6 to generate a Netlist 980 which may contain design structures such as design structure 920. Netlist 980 may comprise, for example, compiled or otherwise processed data structures representing a list of wires, discrete components, logic gates, control circuits, I/O devices, models, etc. that describe the connections to other elements and circuits in an integrated circuit design. Netlist 980 may be synthesized using an iterative process in which Netlist 980 is resynthesized one or more times depending on design specifications and parameters for the device. As with other design structure types described herein, Netlist 980 may be recorded on a machine-readable data storage medium or programmed into a programmable gate array. The medium may be a non-volatile storage medium such as a magnetic or optical disk drive, a programmable gate array, a compact flash, or other flash memory. Additionally, the medium may be a system or cache memory, buffer space, or electrically or optically conductive devices and materials on which data packets may be transmitted and intermediately stored via the internet, or other suitable networking means.

Design process 910 may include hardware and software modules for processing a variety of input data structure types including Netlist 980. Such data structure types may reside, for example, within library elements 930 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 940, characterization data 950, verification data 960, design rules 950, and test data files 985 which may include input test patterns, output test results, and other testing information. Design process 910 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 910, without deviating from the scope and spirit of the invention. Design process 910 may also include modules for performing standard circuit design processes such as timing analysis, verification, design rule checking, place and route operations, etc.

Design process 910 employs and incorporates logic and physical design tools such as HDL compilers and simulation model build tools to process design structure 920 together with some or all of the depicted supporting data structures, along with any additional mechanical design or data, to generate a second design structure 990. Design structure 990 resides on a storage medium or programmable gate array in a data format used for the exchange of data of mechanical devices and structures (e.g., information stored on an IGES, DXF, Parasolid XT, JT, DRG, or any other suitable format for storing or rendering such mechanical design structures). Similar to design structure 920, design structure 990 preferably comprises one or more files, data structures, or other computer-encoded data or instructions that reside on transmission or data storage media and that, when processed by an ECAD system, generate a logically or otherwise functionally equivalent form of one or more of the embodiments of the invention shown in FIGS. 3, 4, 5, and 6. In one embodiment, design structure 990 may comprise a compiled, executable HDL simulation model that functionally simulates the devices shown in FIGS. 3, 4, 5, and 6.

Design structure 990 may also employ a data format used for the exchange of layout data of integrated circuits and/or symbolic data format (e.g., information stored in a GDSII, GL1, OASIS, map files, or any other suitable format for storing such design data structures). Design structure 990 may comprise information such as symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 2 and 3. Design structure 990 may then proceed to a state 995 where, for example, design structure 990 proceeds to tape-out, is released to manufacturing, is released to a mask house, is sent to another design house, is sent back to the customer, etc.

Although the present invention has been described in terms of specific embodiments, it is anticipated that alterations and modifications thereof may become apparent to those skilled in the art. Therefore, it is intended that the following claims be interpreted as covering all such alterations and modifications as fall within the true spirit and scope of the invention.

1. A domino static random access memory (SRAM) comprising:
two or more SRAM memory cells connected with a local bit line;
a precharge device connected between a voltage supply and the local bit line;
a global bit line (GBL) discharge logic connected with the local bit line and a GBL, wherein the GBL discharge logic is adapted to transfer a logic value of the local bit line to the GBL during a read operation; and
a GBL precharge logic connected with the GBL and a global precharge input, wherein the GBL precharge logic is adapted to draw the GBL to a precharge voltage above a discharge voltage and below the supply voltage during a precharge operation.

2. The SRAM of claim 1, wherein the GBL precharge logic comprises a PFET transistor with a drain connected to the GBL, a source connected to the supply voltage, a gate coupled with the global precharge input, and a precharge feedback path to turn off the PFET transistor at the precharge voltage.

3. The SRAM of claim 1, wherein the GBL precharge logic comprises a keeper feedback path to maintain the GBL at the precharge voltage above the discharge voltage and below the supply voltage following the precharge operation, and until the next GBL discharge operation.

4. The SRAM of claim 3, wherein the keeper feedback path comprises an NFET with a source coupled to the GBL and a drain coupled the supply voltage.

5. The SRAM of claim 1, wherein the GBL precharge logic comprises an NFET transistor having a source connected to the GBL, a drain connected to the supply voltage, and a gate coupled with the global precharge input.

6. The SRAM of claim 1, wherein the GBL discharge logic includes a PFET with a source connected to the GBL, a drain connected to ground, and a gate coupled with the local bit line.

7. The SRAM of claim 1, wherein the GBL discharge logic includes a NFET with a drain connected to the GBL, a source connected to ground, and a gate coupled with the local bit line.

8-11. (canceled)

12. A design structure tangibly embodied in a machine-readable storage medium used in a design process of an SRAM, the design structure having elements that, when processed in a semiconductor manufacturing facility, produce an SRAM that comprises:
one or more SRAM memory cells connected with a local bit line;
a precharge device connected between a supply voltage and the local bit line;
a global bit line (GBL) discharge logic connected with the local bit line and a GBL, wherein the GBL discharge logic is adapted to transfer a logic value of the local bit line to the GBL during a read operation; and
a GBL precharge logic connected with the GBL and a global precharge input, wherein the GBL precharge logic is adapted to draw the GBL to a precharge voltage above a discharge voltage and below the supply voltage during a precharge operation.

13. The design structure of claim 12, wherein the design structure comprises a Netlist which describes the SRAM.

14. The design structure of claim 12, wherein the design structure resides on a storage medium as a data format used for the exchange of layout data of integrated circuits.

15. The design structure of claim 12, wherein the design structure includes at least one set of test data files, characterization data, verification data, or design specifications.

16. The design structure of claim 12, wherein the GBL precharge logic comprises an NFET transistor having a source connected to the GBL, a drain connected to the supply voltage, and a gate coupled with the global precharge input.

17. The design structure of claim 12, wherein the GBL precharge logic comprises a PFET transistor with a drain connected to the GBL, a source connected to the supply voltage, a gate coupled with the global precharge input, and a precharge feedback path to turn off the PFET transistor at the precharge voltage.

18. The design structure of claim 12, wherein the GBL precharge logic comprises a keeper feedback path to maintain the GBL at the voltage above the discharge voltage and below the supply voltage during the precharge operation.

19. The design structure of claim 18, wherein the keeper feedback path comprises an NFET with a source coupled to the GBL and a drain coupled the supply voltage.

20. The design structure of claim 12, wherein the GBL discharge logic includes a PFET with a source connected to the GBL, a drain connected to ground, and a gate coupled with the local bit line.

21. The design structure of claim 12, wherein the GBL discharge logic includes a NFET with a drain connected to the GBL, a source connected to ground, and a gate coupled with the local bit line.
